(19) United States
(12) Patent Application Publication
(10) Pub. No.: US 2025/0336623 A1
(43) Pub. Date: Oct. 30, 2025

(54) BUTTON

(71) Applicant: DARWIN PRECISIONS CORPORATION, Hsinchu County (TW)

(72) Inventor: HSING-YU CHEN, Hsinchu County (TW)

(21) Appl. No.: 19/023,414

(22) Filed: Jan. 16, 2025

(30) Foreign Application Priority Data
Apr. 30, 2024 (TW) 113116246

(51) Int. Cl. H01H 13/14; H01H 13/06

(52) U.S. Cl. CPC H01H 13/14; H01H 13/06

(57) ABSTRACT

A button adapted to be arranged on a plate body. The button includes a front frame, an optical switch module, and a fixing ring. The front frame has a second through hole, an outer flange, a positioning portion, and a storage groove. The outer flange and the positioning portion is respectively provided at a front end and inside of the second through hole. The storage groove is provided in at least a side of the front frame. The optical switch module connected to the front frame and installed in the second through hole. The fixing ring sleeves on the rear end and has an inner ring, an outer ring and a connector connected between the outer ring and the inner ring to form an accommodation space that accommodate the rear end. The inner ring and outer ring are adapted to push against and clamp the substrate and plate body, respectively.

### FIELD OF THE INVENTION

The present invention relates to a button, in particular to an optical trigger button.

### BACKGROUND OF THE INVENTION

A button is a common component used to operate electrical and mechanical equipment. There are various ways to set buttons, for example, when applied to a tool machine, different buttons will be set according to different device functions, while when applied to an elevator, corresponding buttons will be set for each floor. It is understandable that with the complexity of device functions or the increase in the number of target objects, the required number of buttons becomes more and more complex, which greatly increases the installation time of buttons, the number of parts required to form the buttons, the chances of errors during installation, and the possibility of interference between buttons.

Buttons can be divided into contact and non-contact according to the trigger method. Some non-contact buttons have a sensor unit and a light-emitting element that can emit light corresponding to the sensing unit. Due to the complexity of the components, it is important to arrange each component in the limited space of the button to maintain good sensing accuracy and avoid installation difficulties of the button.

### SUMMARY OF THE INVENTION

The invention provides a button that can be installed quickly, maintain good optical-sensing performance, and avoid interference between components during installation.

In order to achieve the above advantages, an embodiment of the present invention provides a button, which is adapted to be arranged on the first through hole of the plate body, and the button includes a front frame, an optical switch module and a fixing ring. The front frame has a second through hole, an outer flange, a positioning portion and a storage groove, wherein the axial direction of the second through hole is the same as the axial direction of the first through hole. The outer flange is arranged at the front end of the second through hole and encloses the second through hole. The positioning portion is arranged in the second through hole and is located between the front end and the rear end of the second through hole. In addition, the positioning portion has a contact surface facing the rear end. The storage groove is arranged in at least one side wall surface of the front frame. The optical switch module is connected to the front frame, and the optical switch module includes a substrate, a light-emitting component, and an optical trigger switch, one of the light-emitting component and the optical trigger switch is installed on the substrate, and the other one of the light-emitting component and the optical trigger switch is installed in the storage groove. A fixing ring is adapted to be sleeved on the rear end and has an inner ring, an outer ring, and a connector connected between the outer ring and the inner ring. The inner ring, the outer ring and the connector jointly surround the accommodation space. The accommodation space is adapted to accommodate the rear end when the fixing ring is connected with the front frame. The inner ring is adapted to push against the substrate to press the contact surface, and the outer ring is adapted to clamp the plate body together with the outer flange.

In one embodiment, the distance between the end face of the outer ring and the outer flange is equal to the thickness of the plate body.

In one embodiment, the button further includes a gasket, wherein the gasket is arranged between the substrate and the inner ring.

In one embodiment, the inner ring is provided with a connecting component on the wall surface of one side facing the accommodation space, and the inner ring is assembled to the rear end through the connecting component.

In one embodiment, the connecting component is a screw groove, and a screw thread is arranged on the inner wall surface close to the rear end.

In one embodiment, the button further includes an optical imaging module, the optical imaging module is installed between the substrate and the front end, and is adapted to generate a stereoscopic optical image projected in front of the front end.

In one embodiment, the button further includes a contact switch and a pressing component, the contact switch is arranged on a substrate. The pressing component is arranged between the substrate and the front end, and the pressing component is adapted to press the contact switch.

In one embodiment, the first groove opening of the storage groove is located on the radial inner wall of the front frame and is between the front end and the positioning portion. The first groove opening is close to the front end and faces the center of the second through hole.

In one embodiment, the storage groove further includes a second groove opening. The second groove opening is located on the radial outer wall surface of the front frame and is between the front end and the positioning portion.

In summary, during the installation, the button of the present invention can simultaneously fix the position of the electronic part (substrate) in the button and the position of the button on the plate body through the fixing ring having an outer ring and an inner ring, so the button has the advantage of quick installation. In addition, the button can be installed on the plate bodies with different thicknesses by providing a gasket between the inner ring and the electronic component to change the distance between the front end of the front frame and the outer ring. In addition, the button can have the functions of both a contact switch and a non-contact switch by installing a movable pressing component and a pressing switch therein.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

The present invention will become more readily apparent to those ordinarily skilled in the art after reviewing the following detailed description and accompanying drawings, in which:

FIG. 1 is a schematic diagram of the decomposition of the button of an embodiment;

FIG. 2 is the cross-sectional schematic diagram of the button of FIG. 1;

FIG. 3 is the decomposition schematic diagram of the button matching gasket of FIG. 1 when it is installed on the plate body with different thicknesses; and

FIG. 4 is a schematic cross-sectional diagram of the button with a gasket in FIG. 3.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

In the following article, the terms used in the description of embodiments based on the present invention, such as: the description of the orientation or positional relationship indicated by “up”, “down”, etc., are described according to the orientation or positional relationship shown in the schema used, and the above terms are only for convenience in describing the present invention and are not for limiting the present invention, That is, the components mentioned must not be indicated or implied to be in a specific orientation, constructed in a specific orientation. In addition, the terms “first” and “second” mentioned in this specification or in the scope of the patent application are only used to name the name of the component (element) or to distinguish different embodiments or scopes, and are not used to limit the upper or lower limit on the number of components.

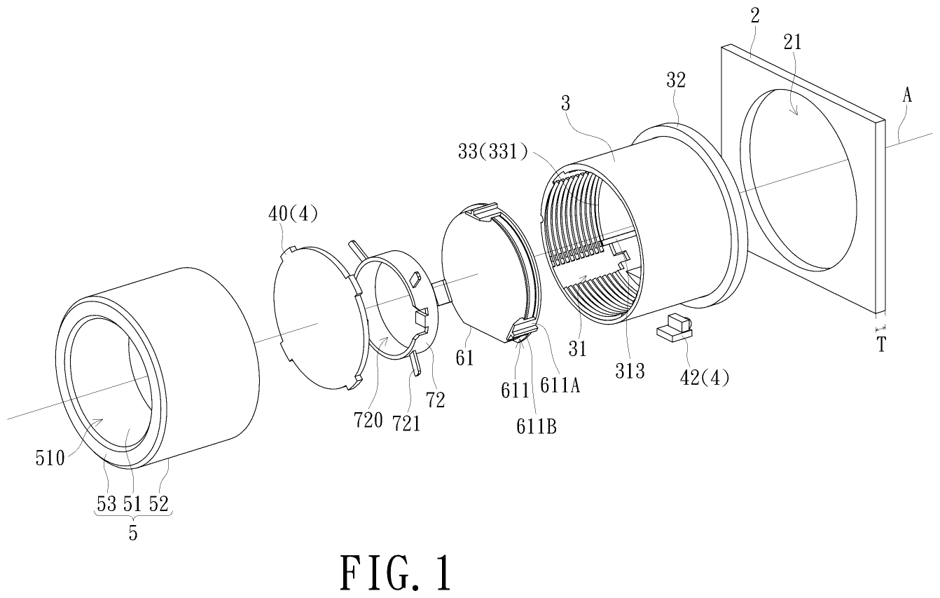

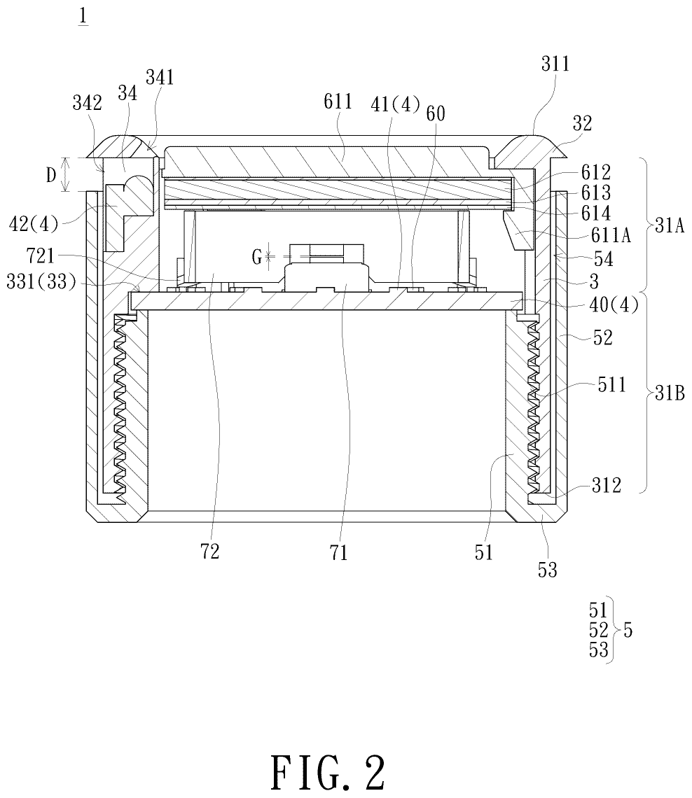

FIG. 1 is a schematic diagram of the decomposition of a button of an embodiment. FIG. 2 is a schematic cross-sectional view of the button in FIG. 1. In FIG. 1, the front frame 3 has been installed on the plate body 2. As shown in FIG. 1, the button 1 provided in this embodiment is adapted to be arranged in the first through hole 21 of the plate body 2. The button 1 includes a front frame 3, an optical switch module 4, and a fixing ring 5. As shown in FIG. 1 and FIG. 2, the front frame 3 has a second through hole 31, an outer flange 32, a positioning portion 33, and a storage groove 34. The axial direction of the second through hole 31 is the same as the axial direction of the first through hole 21 (see the extension direction of the axis A in FIG. 1), and the outer flange 32 is arranged at a front end 311 of the second through hole 31 and encloses the second through hole 31. The positioning portion 33 is arranged in the second through hole 31 and is located between the front end 311 (see FIG. 2) and a rear end 312 (see FIG. 2) of the second through hole 31, and the positioning portion 33 has a contact surface 331 facing the rear end 312. The storage groove 34 is arranged in at least one side wall surface of the front frame 3 and is close to the front end 311. The optical switch module 4 is connected to the front frame 3. The optical switch module 4 includes a substrate 40, a light-emitting component 41, and an optical trigger switch 42. One of the light-emitting component 41 and the optical trigger switch 42 is installed on the substrate 40, and the other is installed in the storage groove 34 (in the embodiment shown in FIG. 2, the light-emitting component 41 is installed on the substrate and the optical trigger switch 42 is installed in the storage groove 34). The fixing ring 5 is adapted to be sleeved on the rear end 312. The fixing ring 5 has an inner ring 51, an outer ring 52, and a connector 53 connected between the outer ring 52 and the inner ring 51. The inner ring 51, the outer ring 52, and the connector 53 jointly surround to form an accommodation space 54. The accommodation space 54 is adapted to accommodate the rear end 312 when the fixing ring 5 is sleeved on and connected with the front frame 3. The inner ring 51 is adapted to push against the substrate 40 to press the contact surface 331. The outer ring 52 is adapted to clamp the plate body 2 together with the outer flange 32.

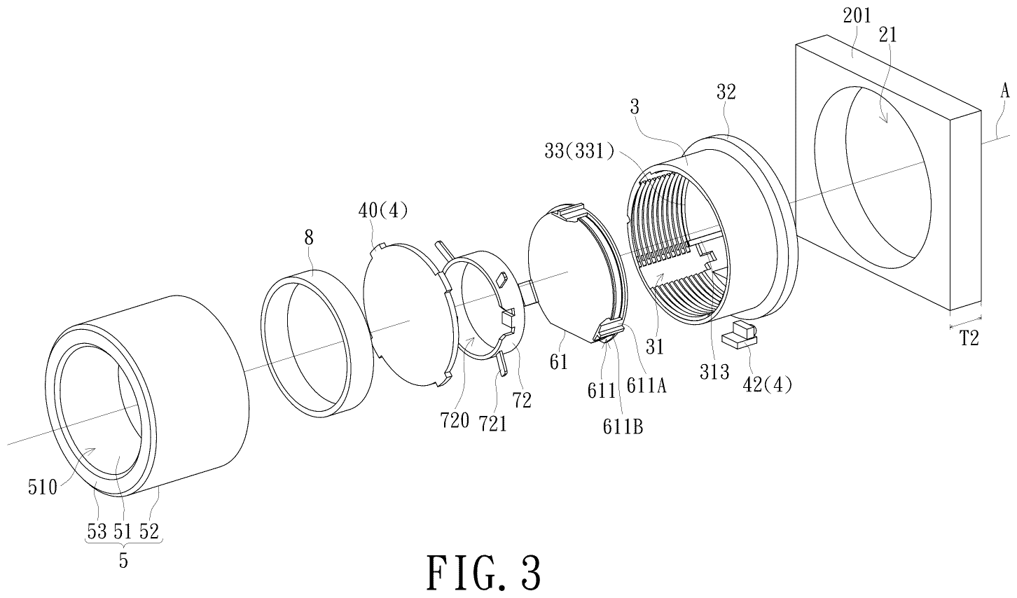

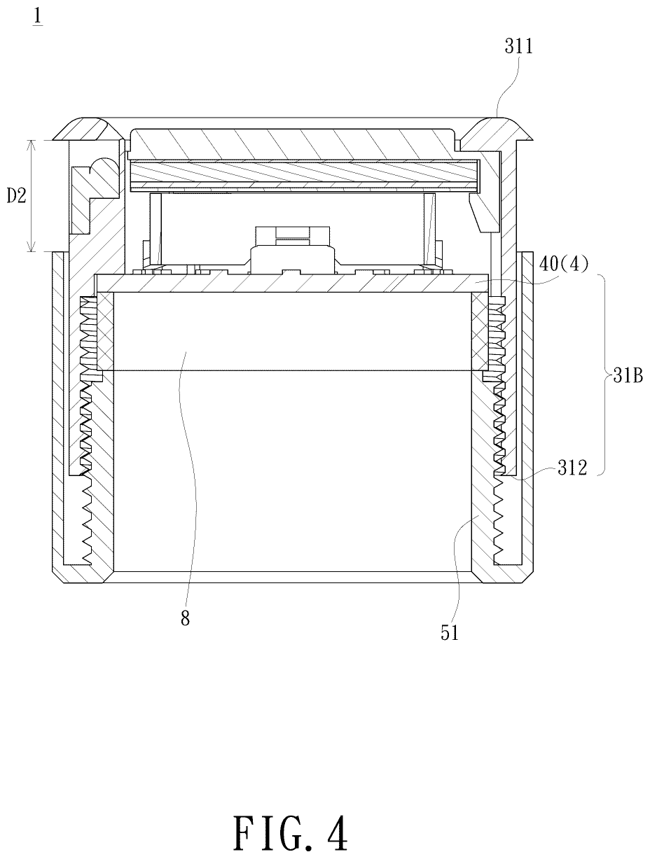

Specifically, the device for using the button 1 of the present embodiment is not particularly restricted, so that the plate body 2 is, for example, a part of the housing of a tool machine or can be a panel of an elevator. The shape of the first through hole 21 of the plate body 2 corresponds, for example, to the shape of the front frame 3, but is not limited to this. The distance D between the end face of the outer ring 52 and the outer flange 32 is, for example, equal to the thickness T of the plate body 2, and the thickness T of the plate body 2 is preferably sufficient to support the weight of the button 1. However, the distance D between the end face of the outer ring 52 and the outer flange 32 is not limited by this (see the embodiment of FIG. 3 and FIG. 4 described below).

Please refer to FIG. 2 and FIG. 3. In this embodiment, the front frame 3 is adapted to accommodate the electronic parts (such as light-emitting components 41 and etc.) required for the button 1. In terms of specific structure, the front frame 3 can be, for example, a cylindrical object, and the outline of the outer wall surface of the front frame 3 corresponds to the shape of the first through hole 21, but is not limited to this. For example, the contour shape of the second through hole 31 on the inner wall surface of the front frame 3 is a round hole, but the contour shape of the second through hole 31 is not particularly restricted and can be adjusted according to the appearance of the button 1.

As shown in FIG. 2, in the present embodiment, the outer flange 32 is located at the front end 311 of the front frame 3 and encloses the second through hole 31. For example, the outer flange 32 extends radially along the axis A of the second through hole 31 in a direction away from the second through hole 31 and protrudes from the outer surface of other parts of the front frame 3 (such as the rear end 312 or the part between the front end 311 and the rear end 312). There is no restriction on the specific contour shape of the outer flange 32, and the contour shape of the outer flange 32 can be, for example, similar to the contour shape of the second through hole 31 or can be selected according to the requirements.

As shown in FIG. 1 and FIG. 2, in the present embodiment, the second through hole 31 includes, for example, a first cylinder 31A and a second cylinder 31B that communicate with each other but have different inner diameters formed by the inner diameter changes between the front end 311 and the rear end 312. The first cylinder 31A is located in the part of the front frame 3 close to the front end 311. The second cylinder 31B is located in the part of the front frame 3 close to the rear end 312. The inner diameter of the first cylinder 31A is smaller than the inner diameter of the second cylinder 31B. The first cylinder 31A forms a space adapted to accommodate the electronic components (such as light-emitting components 41 and etc.) inside the button 1. The second cylinder 31B forms a space adapted to accommodate the wiring of the button 1 and the inner ring 51 of the fixing ring 5. In this embodiment, the junction between the first cylinder 31A and the second cylinder 31B (where the inner diameter changes, presenting a stepped structure) constitutes the positioning portion 33, and one side of the stepped structure facing the rear end 312 constitutes the contact surface 331. The substrate 40 enters the second through hole 31 from the rear end 312 and can be pushed by the positioning portion 33 at the time of installation.

The second through hole 31 and its internal structure are not limited to the above examples. In other embodiments not shown, the second through hole 31 may be a cylinder with a constant inner diameter, and the positioning portion 33 may be other known position-limiting structures such as a position-limiting block (not shown in the figures.) protruding from the wall surface of the second through hole 31. In addition, because the position of the substrate 40 can be restricted through the positioning portion 33, the shape and size of the front end 311 of the second through hole 31 may be different from the shape and size of the rear end 312 and the shape of the substrate 40 can be changed according to the requirements in the embodiment not shown in the figures.

As shown in FIG. 2, in this embodiment, the storage groove 34 is located in the wall surface of at least one side of the front frame 3 close to the front end 311. The storage groove 34 has, for example, a first groove opening 341 located at the front end 311 and formed on the inner wall surface of the front frame 3, and a second groove opening 342 formed on the outer wall surface of the front frame 3. The second groove opening 342 is adapted to allow the optical trigger switch 42 to enter the storage groove 34 along the radial direction of the second through hole 31, but the specific shape of the second groove opening 342 is not limited by this. It should be understandable that the second groove opening 342 may not be provided in the embodiment not shown in the figures. For example, the axial direction of the first groove opening 341 is inclined to the axial direction of the second through hole 31, thus, the first groove opening 341 of the storage groove 34 is not covered by the plate body 2 after the buttons 1 of the present embodiment is assembled to the plate body 2. The component to be installed in the storage groove 34 (the optical trigger switch 42 in this embodiment) can enter the storage groove 34 from the second groove opening 342 without passing through the first groove opening 341.

In terms of the specific structure of the optical switch module 4, the substrate 40 in this embodiment as shown in FIG. 1 and FIG. 2 is a printed circuit board, but is not limited to this. During assembling, the substrate 40 is located between the first cylinder 31A and the second cylinder 31B, and the edge of the substrate 40 contacts the contact surface 331 of the positioning portion 33. For example, the light-emitting component 41 is located on the substrate 40 and faces the front end 311. The light beam emitted by the light-emitting component 41 is an infrared beam, for example, but is not limited to this. The optical trigger switch 42 is arranged, for example, in the storage groove 34, and the optical trigger switch 42 senses toward the center of the second through hole 31 and is adapted to sense the light beam generated by the light-emitting component 41 and reflected back by the user's finger, wherein the wavelength of the light beam sensed by the optical trigger switch 42 corresponds to the wavelength of the light beam generated by the light-emitting component 41. When the user's finger (not shown in the figures) approaches the button 1, the light beam emitted by the light-emitting component 41 can be reflected by the finger, enter the storage groove 34 by the first groove opening 341 of the first groove, and triggers the optical trigger switch 42. A control signal of a control device (not shown in the figures) will be generated after the optical trigger switch 42 is triggered, for example. The specific position and type of the light-emitting component 41 and the optical trigger switch 42 are not limited by this.

In terms of the specific structure of the fixing ring 5, the inner ring 51 in this embodiment is a ring corresponding to the shape of the inner wall surface of the second through hole 31 and allows a wire or wires connected to the substrate 40 (not shown in the figures) to pass therethrough. The ring opening 510 in the center of the inner ring 51 is provided for, for example, a circuit (not shown in the figures) connected to the substrate 40 to pass therethrough. The height of the inner ring 51 (along the axis A or the extension direction of the fixing ring 5) is, for example, greater than the distance between the rear end 312 and the substrate 40 (see FIG. 2), so that the substrate 40 is pushed against by the inner ring 51 and therefore the contact surface 331 when the fixing ring 5 is connected to the front frame 3. The inner ring 51 is provided with a connecting component 511 on a wall surface of the inner ring facing the accommodation space 54 and the inner ring 51 is assembled to the rear end 312 of the front frame 3 through the connecting component 511, as shown in FIG. 1 and FIG. 2. The connecting component 511 is, for example, a screw groove, and the front frame 3 is provided with a screw thread corresponding to the screw groove on an inner wall surface close to the rear end 312.

The shape of the outer ring 52 corresponds, for example, to the shape of the inner ring 51, but is not limited to this. The height of the outer ring 52 (along the extension direction of the fixing ring 5) corresponds to the distance between the rear end 312 and the plate body 2, for example, and is also greater than the height of the inner ring 51. There is no restriction on the structure of the connector 53 as long as the connector 53 can connect the inner ring 51 and the outer ring 52 and forms the accommodation space 54 between the inner ring 51 and the outer ring 52 and capable of accommodating the rear end 312 of the front frame 3.

Through the above structure, because the distance between the outer ring 52 and the outer surface of the front frame 3 can be increased through the connector 53, the connection structure between the front frame 3 and the fixing ring 5 does not affect the shape of the outer surface of the front frame 3 (the second through hole 31) when the front frame 3 is connected with the fixing ring 5, and therefore the outer ring 52 can be prevented from affecting the design of the storage groove 34 or affecting the components in the storage groove 34. In addition, once the installation of the fixing ring 5 is completed, the positioning between the substrate 40 and the front frame 3 and the positioning between the front frame 3 and the plate body 2 are also completed.

It should be understood that in the above embodiment, although the connecting component 511 is located on the inner ring 51, the user can adjust the detailed position of the inner ring 51 on the front frame 3 by holding a part of the outer ring 52 when installing the button 1 on the plate body 2 due to the inner ring 51 is connected with the outer ring 52 through the connector 53. In addition, because the connecting component 511 is located in the accommodation space 54, the connecting component can be protected by the inner ring 51, the outer ring 52, and the connector 53.

In addition, the type of the connecting component 511 is not limited to the above examples such as a screw thread and a screw groove. In the embodiment not shown in the figures, the connecting component 511 on the inner ring 51 may be changed to an elastic piece with a bump, and the front frame 3 may be provided with a clamping groove or a buckle hole corresponding to the position of the elastic piece and the bump on the inner wall surface close to the rear end 312. In addition, because the outer ring 52 is mainly used to fix the front frame 3 on the plate body 2, the shape of the outer ring 52 can be changed to other shapes according to the requirements to have a shape similar to or different to the shape of the inner ring 51 in other embodiments not shown in the figures.

As shown in FIG. 1 and FIG. 2, the button 1 in the present embodiment further includes a light-emitting unit 60 and an optical imaging module 61. The light-emitting unit 60 is arranged on a substrate 40, for example. The light-emitting unit 60 is a light-emitting diode, for example. The wavelength range of the light beam generated by the light-emitting unit 60 is a wavelength range between visible light, for example. The optical imaging module 61 is installed between the optical switch module 4 and the front end 311 and covers the light-emitting unit 60 and the light-emitting component 41. The optical imaging module 61 is adapted to convert the light beam generated by the light-emitting unit 60 into a stereoscopic optical image (not shown in the figures) projected in front of the front end 311. Because there is no special restriction on the type relationship between the light-emitting unit 60 and the light-emitting component 41, the light-emitting component 41 can also serve as the light-emitting unit 60 when the optical trigger switch 42 has a corresponding type in other embodiments.

Specifically, as shown in FIG. 2, the optical imaging module 61 includes a front cover 611, a lens array 612, a pattern layer 613, and a collimating unit 614 in order, but is not limited to this. The front cover 611 is, for example, a light-transparent part. The periphery of the front cover 611 has, for example, a plurality of clamping blocks 611A adapted to clamp the assembly of the lens array 612, the pattern layer 613, and the collimating unit 614. As shown in FIG. 1 and FIG. 2, the clamping block 611A is provided with a convex rail 611B, and the inner wall surface of the first cylinder 31A is provided with a sliding groove 313 corresponding to the shape of the convex rail 611B, so that the optical imaging module 61 can slide in the first cylinder 31A along the extension direction of the axis A and approach or move away from the substrate 40.

The collimating unit 614 is arranged on one side of the optical imaging module 61 facing the light-emitting unit 60 and is adapted to convert the light beam generated by the light-emitting unit 60 in various directions into the collimating light beam approximately parallel to the extension direction of the axis A and emitted from the second through hole 31. Specifically, the collimating unit 614 is, for example, a Fresnel lens, but is not limited to this.

The pattern layer 613 covers the collimating unit 614. The pattern layer 613 is adapted to generate an optical pattern. The pattern layer 613 is, for example, composed of a light-transmitting layer with a pattern or a light-blocking layer with a pattern opening, but is not limited to this. The lens array 612 is located between the pattern layer 613 and the front cover 611. The lens array 612 includes, for example, a plurality of microlenses (not shown in the figures). The lens array 612 is adapted to convert a light beam passing through the pattern layer 613 into a stereoscopic optical image.

From the above, it can be seen that because the light-emitting component 41 in this embodiment is arranged on the substrate 40 and covered by the optical imaging module 61, the light beam generated by the light-emitting component 41 can pass through the collimating unit 614, thereby avoiding the problem in which the light beam at the front part of the button 1 is difficult to reflect due to the angle. Thus, the sensing accuracy can be improved. However, it is understood that the positions of the light-emitting component 41 and the optical trigger switch 42 are not limited by this and can be interchanged from each other.

As shown in FIG. 1 and FIG. 2, the button 1 in the present embodiment further includes, for example, a contact switch 71 and a pressing component 72. The contact switch 71 is, for example, a tact switch or other existing contact switch. The contact switch 71 is arranged on the substrate 40, for example (and is positioned by the side of the light-emitting unit 60).

The pressing component 72 is, for example, a frame covering the contact switch 71, but is not limited to this. As shown in FIG. 1, the pressing component 72 has an opening 720 for the light beam generated by the light-emitting component 41 and the light-emitting unit 60 on the substrate 40 to pass through. The pressing component 72 is, for example, provided with a plurality of elastic arms 721 extending towards the substrate 40 on the outer surface. The pressing component 72 pushes against the substrate 40 through the elastic arm 721 so that one end of the pressing component 72 close to the substrate 40 is separated from the contact switch 71 on the substrate 40 by a gap G. The other end of the pressing component 72 pushes against the optical imaging module 61 so that the optical imaging module 61 keeps a fixed gap with the substrate 40 when it is not pushed.

In this embodiment, when the user presses the front cover 611, the optical imaging module 61 moves toward the substrate 40, changes the shape of the elastic arm 721, reduces the gap G, and then indirectly presses the contact switch 71 on the substrate 40 through the pressing component 72, so that the contact switch 71 generates a control signal. In other words, the button 1 of the present embodiment can be a contact button.

It should be understood that in the embodiment not shown in the figures, the optical imaging module 61 can be directly used as the pressing component 72 by changing the shape, type, or setting position of the contact switch 71. In addition, an elastic part (such as a spring, etc.) can be arranged on the substrate 40 without the need for the elastic arm 721.

FIG. 3 is a schematic diagram of the decomposition of the button and gasket in FIG. 1 when it is installed on a plate with different thicknesses of the plate body. FIG. 4 is a schematic cross-sectional diagram of the button with a gasket in FIG. 3. Please refer to FIG. 3 and FIG. 4, the button 1 in this embodiment further includes a gasket 8 installed on a plate body 201 having a thickness different from that of the plate body 2. For example, the gasket 8 is arranged in the second cylinder 31B and contacts the substrate 40 and the inner ring 51. Because the inner ring 51 connects the outer ring 52 through the connector 53, the distance between the outer ring 52 and the outer flange 32 is changed to distance D2 when the distance between the substrate 40 and the inner ring 51 is changed through the gasket 8, and the magnitude of the distance D2 is the magnitude of the distance D plus the thickness of the gasket 8. In other words, with different gaskets 8 or without using gaskets 8, the same button 1 can be installed on the plates 201 of different thicknesses T2 without changing the structure.

In summary, during the installation of the button of the present invention, the position of the electronic component (substrate) in the button and the position of the button on the plate body can be fixed simultaneously through a fixing ring having an outer ring and an inner ring, and therefore the button has the advantage of quick installation. In addition, the button of the present invention can be installed on the plate bodies with different thicknesses by providing a gasket between the inner ring and the electronic component to change the distance between the front end of the front frame and the outer ring. In addition, the button of the present invention can function as a contact switch and a non-contact switch both by installing a movable pressing component and a pressing switch therein.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A button adapted to be arranged in a first through hole of a plate body, and the button comprising:
a front frame, having a second through hole, an outer flange, a positioning portion, and a storage groove, wherein an axial direction of the second through hole is the same as an axial direction of the first through hole, the outer flange is arranged at a front end of the second through hole and encloses the second through hole, the positioning portion is arranged in the second through hole and is located between the front end and a rear end of the second through hole, the positioning portion has a contact surface facing the rear end, and the storage groove is arranged in at least one side-wall surface of the front frame;
an optical switch module, connected to the front frame, wherein the optical switch module comprises a substrate, a light-emitting component, and an optical trigger switch, one of the light-emitting component and the optical trigger switch is installed on the substrate, and the other one of the light-emitting component and the optical trigger switch is installed in the storage groove;
a fixing ring, adapted to be sleeved on the rear end, wherein the fixing ring has an inner ring, an outer ring, and a connector connected between the outer ring and the inner ring, the inner ring, the outer ring, and the connector jointly surround an accommodation space, the accommodation space is adapted to accommodate the rear end when the fixing ring is connected to the front frame, the inner ring is adapted to push against the substrate to press the contact surface, and the outer ring is adapted to clamp the plate body together with the outer flange.

2. The button according to claim 1, wherein a distance between an end face of the outer ring and the outer flange is equal to a thickness of the plate body.

3. The button according to claim 1, further comprising a gasket, wherein the gasket is arranged between the substrate and the inner ring.

4. The button according to claim 1, wherein the inner ring is provided with a connecting component on a wall surface of the inner ring facing the accommodation space, and the inner ring is assembled to the rear end through the connecting component.

5. The button according to claim 4, wherein the connecting component is a screw groove, and the front frame is provided with a screw thread on an inner wall surface close to the rear end.

6. The button according to claim 1, further comprising an optical imaging module, wherein the optical imaging module is installed between the substrate and the front end and is adapted to generate a stereoscopic optical image projected in front of the front end.

7. The button according to claim 1, further comprising a contact switch and a pressing component, wherein the contact switch is arranged on the substrate, the pressing component is arranged between the substrate and the front end, and the pressing component is adapted to press the contact switch.

8. The button according to claim 1, wherein the storage groove comprises a first groove opening, and the first groove opening is located on an inner wall surface of the front frame and between the front end and the positioning portion.

9. The button according to claim 1, wherein the storage groove comprises a second groove opening, and the second groove opening is located on an outer wall surface of the front frame and is between the front end and the positioning portion.
